(19) United States
(12) Patent Application Publication
(10) Pub. No.: US 2023/0416901 A1
(43) Pub. Date: Dec. 28, 2023

(54) APPARATUS FOR MANUFACTURING DISPLAY DEVICE, MASK ASSEMBLY, AND METHOD OF MANUFACTURING DISPLAY DEVICE

(71) Applicant: Samsung Display Co., Ltd., Yongin-si (KR)

(72) Inventors: Dahee Jeong, Yongin-si (KR); Sangha Park, Yongin-si (KR); Seungyong Song, Yongin-si (KR); Eunbee Jo, Yongin-si (KR); Youngsuck Choi, Yongin-si (KR); Kyuhwan Hwang, Yongin-si, Gyeonggi-do (KR)

(73) Assignee: Samsung Display Co., Ltd., Yongin-si (KR)

(21) Appl. No.: 18/125,885

(22) Filed: Mar. 24, 2023

(30) Foreign Application Priority Data
Jun. 27, 2022 (KR) 10-2022-0078472

(51) Int. Cl. C23C 14/04; H10K 59/12; C23C 14/24

(52) U.S. Cl. CPC C23C 14/042; C23C 14/24; H10K 59/1201

(57) ABSTRACT

An apparatus for manufacturing a display device includes a mask assembly that includes a mask frame including an opening area, at least one shield stick fixed on the mask frame in a tensioned state across the opening area of the mask frame, and a plurality of mask sheets covering at least part of the opening area of the mask frame and at least partially overlapping the at least one shield stick. The at least one shield stick includes a first shield member, a second shield member at least partially overlapping the first shield member, and a third shield member at least partially overlapping the first shield member. The second shield member and the third shield member are disposed above the first shield member and are closer to the plurality of mask sheets than the first shield member is close to the plurality of mask sheets.

### CROSS-REFERENCE TO RELATED APPLICATION(S)

This application claims priority to and benefits of Korean Patent Application No. 10-2022-0078472 under 35 U.S.C. § 119, filed on Jun. 27, 2022, in the Korean Intellectual Property Office (KIPO), the entire contents of which are incorporated herein by reference.

### BACKGROUND

### 1. Technical Field

One or more embodiments relate an apparatus for manufacturing a display device, a mask assembly, and a method of manufacturing the display device.

### 2. Description of the Related Art

Recently, electronic devices have been widely used. Electronic devices have been variously used as mobile electronic devices and fixed electronic devices. Such electronic devices include display apparatuses that provide a user with visual information such as images or videos to support various functions.

A display apparatus visually displays data and is formed by depositing various layers such as an organic layer, a metal layer, and the like. To form layers of a display apparatus, a deposition material may be deposited. As a deposition material is sprayed from a deposition source, the deposition material is deposited on a substrate through a mask assembly. In case that an interference phenomenon occurs between a mask sheet and a shield stick, the deposition material is not deposited at a required position on the substrate so that deposition quality is lowered.

### SUMMARY

Embodiments provide an apparatus for manufacturing a display device, which may improve the deposition quality of a deposition material by preventing an interference phenomenon between a mask sheet and a shield stick, a mask assembly, and a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, an apparatus for manufacturing a display device may include a chamber, a mask assembly disposed in the chamber and facing a display substrate, and a deposition source disposed in the chamber and facing the mask assembly, the deposition source that supplies a deposition material such that the deposition material passes through the mask assembly and is deposited on the display substrate. The mask assembly may include a mask frame including an opening area, at least one shield stick fixed on the mask frame in a tensioned state across the opening area, and a plurality of mask sheets covering at least part of the opening area and at least partially overlapping the at least one shield stick. The at least one shield stick may include a first shield member, a second shield member at least partially overlapping the first shield member, and a third shield member at least partially overlapping the first shield member. The second shield member and the third shield member may be disposed above the first shield member and are closer to the mask sheet than the first shield member is close to the mask sheet.

In an embodiment, a shield stick groove may be disposed in the mask frame and may accommodate end portions of the at least one shield stick.

In an embodiment, in case that the at least one shield stick is accommodated in the shield stick groove, the first shield member may be fixed on the mask frame.

In an embodiment, in case that the at least one shield stick is accommodated in the shield stick groove, the second shield member and third shield member may be fixed on the mask frame.

In an embodiment, the at least one shield stick may include at least one of a stainless material and an invar material.

In an embodiment, the at least one shield stick may further include a fourth shield member at least partially overlapping the third shield member, disposed below the third shield member, and being closer to the deposition source than the third shield member is close to the deposition source, and a fifth shield member at least partially overlapping the fourth shield member, disposed above the fourth shield member, and being closer to the mask sheet than the fourth shield member is close to the mask sheet.

According to one or more embodiments, a mask assembly may include a mask frame including an opening area, at least one shield stick fixed on the mask frame in a tensioned state across the opening area, and a plurality of mask sheets covering at least part of the opening area and at least partially overlapping the at least one shield stick, wherein the at least one shield stick may include three or more shield members, two shield members of the three or more shield members may be adjacent to each other and may at least partially overlap each other, and at least one of the three or more shield members may be disposed below the two shield members that are adjacent to each other.

In an embodiment, a shield stick groove may be disposed in the mask frame and may accommodate end portions of the at least one shield stick.

In an embodiment, in case that the at least one shield stick is accommodated in the shield stick groove, at least one of the three or more shield members may be fixed on the mask frame.

In an embodiment, in case that the at least one shield stick is accommodated in the shield stick groove, the three or more shield members may be fixed on the mask frame.

In an embodiment, the at least one shield stick may include at least one of a stainless material and an invar material.

According to one or more embodiments, a method of manufacturing a display device may include arranging a display substrate and a mask assembly in a chamber, depositing a deposition material on the display substrate, the deposition material being supplied from a deposition source to pass through the mask assembly, and cleaning the mask assembly, wherein the mask assembly may include a mask frame including an opening area of the mask frame, at least one shield stick fixed on the mask frame in a tensioned state across the opening area of the mask frame, and a plurality of mask sheets covering at least part of the opening area of the mask frame and at least partially overlapping the at least one shield stick, wherein the at least one shield stick may include a first shield member, a second shield member at least partially overlapping the first shield member, and a third shield member at least partially overlapping the first shield member, and wherein the second shield member and the third shield member may be disposed above the first shield member and may be closer to the mask sheet than the first shield member is close to the mask sheet.

In an embodiment, a strain that is a ratio of the length of a shield stick deformed due to a temperature difference in the cleaning of the mask assembly to the length of a shield stick tensioned in the disposing of the display substrate and the mask assembly may be about 0% or more and about 0.03% or less.

In an embodiment, the width of the at least one shield stick may be determined such that a strain of the at least one shield stick is about 0% or more and about 0.03% or less.

In an embodiment, a degree of tensioning the at least one shield stick before the at least one shield stick is fixed on the mask frame is determined such that a strain of the at least one shield stick may be about 0% or more and about 0.03% or less.

In an embodiment, a shield stick groove may be disposed in the mask frame and may accommodate end portions of the at least one shield stick.

In an embodiment, in case that the at least one shield stick is accommodated in the shield stick groove, the first shield member may be fixed on the mask frame.

In an embodiment, in case that the at least one shield stick is accommodated in the shield stick groove, the second shield member and third shield member may be fixed on the mask frame.

In an embodiment, the at least one shield stick may include at least one of a stainless material and an invar material.

In an embodiment, the at least one shield stick may further include a fourth shield member at least partially overlapping the third shield member, disposed below the third shield member, and being closer to the deposition source than the third shield member is close to the deposition source, and a fifth shield member at least partially overlapping the fourth shield member, disposed above the fourth shield member, and being closer to the mask sheet than the fourth shield member is close to the mask sheet.

Other aspects, features, and advantages than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display device, according to an embodiment;

FIG. 2 is a schematic perspective view of a mask assembly according to an embodiment;

FIGS. 3A, 3B, and 3C are schematic diagrams for explaining a process of a shield stick according to an embodiment being fixed on a mask frame;

FIG. 4 is a schematic side view of a part of a mask assembly according to an embodiment;

FIG. 5 is a schematic side view of a part of a mask assembly according to an embodiment;

FIG. 6 is a schematic plan view of a display device manufactured by a method of manufacturing a display device, according to an embodiment; and

FIG. 7 is a schematic cross-sectional view of a display device manufactured by a method of manufacturing a display device, according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

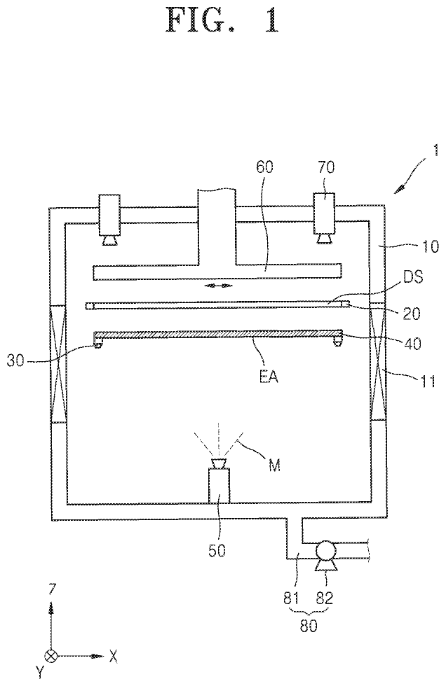

FIG. 1 is a schematic cross-sectional view of an apparatus 1 for manufacturing a display device, according to an embodiment.

The apparatus 1 for manufacturing a display device may include a chamber 10, a first support portion 20, a second support portion 30, a mask assembly 40, a deposition source 50, a magnetic force unit 60, a vision unit 70, and a pressure control unit 80.

The chamber 10 may have a space formed inside, and a display substrate DS and the mask assembly 40 may be accommodated in the space of the chamber 10. For example, the chamber 10 may be partially opened, and a gate valve 11 may be provided in the opening portion of the chamber 10. For example, the opening portion of the chamber 10 may be open or closed according to the operation of the gate valve 11.

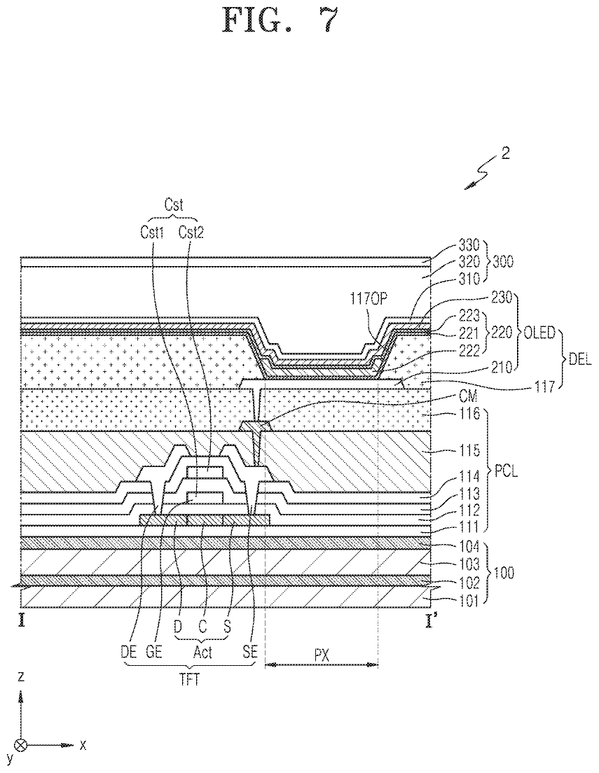

For example, the display substrate DS may be under manufacturing of a display device, in which at least one of an organic layer, an inorganic layer, and a metal layer deposited on a substrate 100 (see FIG. 7) to be described below. In another example, the display substrate DS may be the substrate 100 on which none of an organic layer, an inorganic layer, and a metal layer is deposed yet.

The first support portion 20 may support the display substrate DS. For example, the first support portion 20 may be in the form of a plate fixed in the chamber 10. In another example, the first support portion 20 may be in the form of a shuttle in which the display substrate DS is placed, and capable of linear motion in the chamber 10. In another example, the first support portion 20 may include an electrostatic chuck or an adhesive chuck fixed to the chamber 10 or arranged in the chamber 10 to be capable of moving in the chamber 10.

The second support portion 30 may support the mask assembly 40. For example, the second support portion 30 may be arranged in the chamber 10. The second support portion 30 may finely adjust the position of the mask assembly 40. For example, the second support portion may include a separate drive unit or alignment unit, and the like, to move the mask assembly in different directions.

In another example, the second support portion 30 may be in the form of a shuttle. For example, the second support portion 30 may accommodate the mask assembly 40 and transfer the mask assembly 40. For example, the second support portion 30 may be moved outside the chamber 10. For example, after the mask assembly 40 is placed on the second support portion the second support portion 30 may enter the chamber 10 from the outside of the chamber 10.

For example, the first support portion 20 and the second support portion 30 may be integral with each other. For example, the first support portion 20 and the second support portion 30 may each include a movable shuttle. For example, the first support portion 20 and the second support portion 30 may each have a structure to fix the mask assembly 40 and the display substrate DS in a state in which the display substrate DS is placed on the mask assembly 40, and it is possible that the display substrate DS and the mask assembly 40 simultaneously perform a linear motion.

However, in the following description, for convenience of explanation, a case in which the first support portion 20 and the second support portion 30 are formed to be distinguished from each other and arranged at different positions, and the first support portion 20 and the second support portion 30 are arranged in the chamber 10 is described in detail.

The mask assembly 40 may be arranged in the chamber 10 to face the display substrate DS. A deposition material M may be deposited on the display substrate DS by passing through the mask assembly 40.

The deposition source 50 may be arranged to face the mask assembly 40, and may supply the deposition material M such that the deposition material M may pass through a deposition area EA of the mask assembly 40 and may be deposited on the display substrate DS. For example, as the deposition source 50 applies heat to the deposition material M, the deposition material M may be vaporized or sublimated. The deposition source 50 may be arranged in the chamber 10 to be fixed thereon or capable of linear motion in a direction.

The magnetic force unit 60 may be arranged in the chamber 10 to face the display substrate DS and/or the mask assembly 40. For example, the magnetic force unit 60 may apply a force to the mask assembly 40 toward the display substrate DS by applying a magnetic force to the mask assembly 40. For example, the magnetic force unit 60 may not only prevent sagging of a mask sheet 44, but also make the mask sheet 44 be adjacent to the display substrate DS. Furthermore, the magnetic force unit 60 may maintain an interval (or gap) between the mask sheet 44 and the display substrate DS constant.

The vision unit 70 may be arranged in the chamber 10, and may capture the positions of the display substrate DS and the mask assembly 40. For example, the vision unit 70 may include a camera for photographing the display substrate DS and the mask assembly 40. The positions of the display substrate DS and the mask assembly 40 may be identified (or measured) based on the image captured by the vision unit 70, and the deformation of the mask assembly 40 may also be identified (or sensed) based thereon. Furthermore, the position of the display substrate DS on the first support portion 20, or the position of the mask assembly 40 on the second support portion 30, may be finely adjusted based on the captured image. In the following description, a case of finely adjusting the position of the mask assembly 40 on the second support portion 30 to align the positions of the display substrate DS and the mask assembly 40 with each other is described in detail.

The pressure control unit 80 may be connected to the chamber 10 and may adjust the pressure in the chamber 10. For example, the pressure control unit 80 may adjust the pressure in the chamber 10 to be identical or similar to the atmospheric pressure. Furthermore, the pressure control unit 80 may adjust the pressure in the chamber 10 to be identical or similar to a vacuum state.

The pressure control unit 80 may include a connection pipe 81 connected to the chamber 10 and a pump 82 provided on the connection pipe 81. For example, according to the operation of the pump 82, external air may be introduced through the connection pipe 81 or a gas in the chamber 10 may be guided to the outside through the connection pipe 81.

In a method of manufacturing a display device by using the apparatus 1 for manufacturing a display device described above, the display substrate DS may be prepared.

The pressure control unit 80 may maintain the inside of the chamber 10 in a state identical or similar to the atmospheric pressure, and may open the open portion of the chamber 10 as the gate valve 11 operates.

For example, the display substrate DS may be loaded into the chamber 10 from the outside. For example, the display substrate DS may be loaded into the chamber 10 in various methods. For example, the display substrate DS may be loaded from the outside of the chamber 10 to the inside of the chamber 10 through a robot arm and the like arranged outside the chamber 10. In another example, in case that the first support portion 20 is formed in the form of a shuttle, it is possible that, after the first support portion 20 is carried from the inside of the chamber 10 to the outside of the chamber 10, the display substrate DS may be placed on the first support portion 20, and the first support portion 20 may be loaded from the outside of the chamber 10 into the chamber 10, through a separate robot arm and the like arranged outside the chamber 10.

The mask assembly 40 may be in a state of being arranged in the chamber 10 as described above. In another example, it is possible to load the mask assembly 40 into the chamber 10 from the outside of the chamber 10 in a manner identical or similar to the display substrate DS.

In case that the display substrate DS is loaded into the chamber 10, the display substrate DS may be placed on the first support portion 20. For example, the vision unit 70 may capture (or sense) the positions of the display substrate DS and the mask assembly 40. The positions of the display substrate DS and the mask assembly 40 may be identified based on the image captured by the vision unit 70. For example, the apparatus 1 for manufacturing a display device may include a separate control unit to identify the positions of the display substrate DS and the mask assembly 40.

In case that the identification of the positions of the display substrate DS and the mask assembly 40 is completed, the second support portion 30 may finely adjust the position of the mask assembly 40.

As the deposition source 50 operates, the deposition material M may be supplied toward the mask assembly 40, and the deposition material M having passed through pattern holes of the mask sheet 44 may be deposited on the display substrate DS. For example, the deposition source 50 may move parallel to the display substrate DS and the mask assembly 40, or the display substrate DS and the mask assembly 40 may move parallel to the deposition source 50. For example, the deposition source 50 may move relative to the display substrate DS and the mask assembly 40. For example, the pump 82 may suck the gas in the chamber 10 and may discharge the gas to the outside so as to maintain the pressure in the chamber 10 in the form identical or similar to vacuum.

As described above, the deposition material M supplied from the deposition source 50 is deposited on the display substrate DS by passing through the mask assembly 40, and accordingly, at least one of layers, for example, an organic layer, an inorganic layer, and a metal layer stacked on a display device to be described below may be formed.

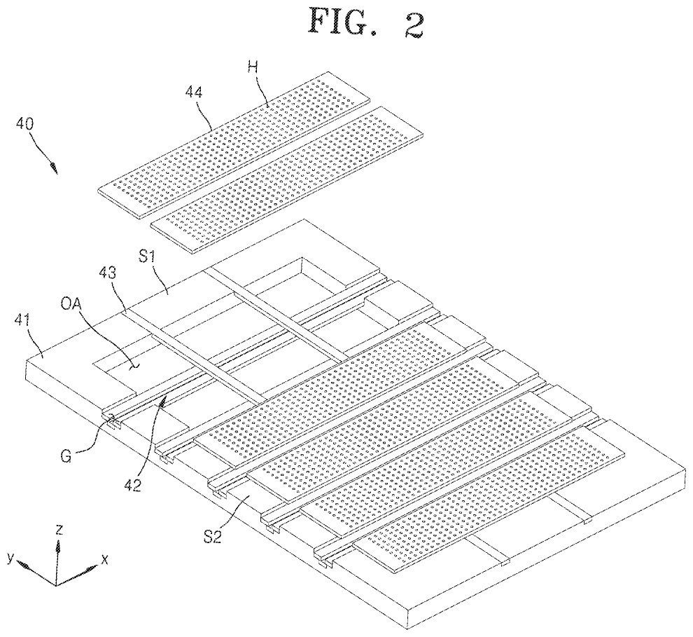

FIG. 2 is a schematic perspective view of a mask assembly according to an embodiment.

Referring to FIG. 2, the mask assembly 40 may include a mask frame 41, a shield stick 42, a support stick 43, and the mask sheet 44.

The mask frame 41 may be formed by connecting sides, and may include an opening area OA defined by the sides. For example, the opening area OA may be surrounded by sides, and the opening area OA may be formed by penetrating the center of the mask frame 41.

In an embodiment, the mask frame 41 may be a rectangular frame. The shape of the mask frame 41 is not limited thereto, and may have various polygonal shapes. In the following description, for convenience of explanation, a case in which the mask frame 41 is a rectangular frame is described.

In case that the mask frame 41 is a rectangular frame, sides may include a first side S1 extending in a first direction, for example, an X-axis direction, and a second side S2 extending in second direction, for example, a Y-axis direction, intersecting the first direction. The first side S1 may include a pair of first sides facing each other, and the second side S2 may include a pair of second sides facing each other, and thus, the first sides and the second sides may be connected to each other. In an embodiment, the first side S1 may be a short side, and the second side S2 may be a long side. However, embodiments are not limited thereto, and the first side S1 may be a long side and the second side S2 may be a short side, or the first side S1 and the second side S2 may have the same length. In the following description, for convenience of explanation, a case in which the first side S1 is a short side and the second side S2 is a long side is described.

The shield stick 42 may be fixed on the mask frame 41 in a tensioned state across the opening area OA. The shield stick 42 may have a length direction in the first direction, for example, the X-axis direction. For example, end portions (e.g., opposite end portions) of the shield stick 42 may be fixed on the mask frame 41 by a welding method. A shield stick groove G may be provided in the mask frame 41 and may have a shape corresponding to the shape of the shield stick 42 to accommodate end portions (e.g., opposite end portions) of the shield stick 42.

The shield stick 42 may be positioned between mask sheets 44 and may shield the deposition material M from passing between the two adjacent mask sheets 44. The shield stick 42 may include shield sticks and may be spaced apart from each other in the second direction, for example, the Y-axis direction, to be parallel to each other.

The shield stick 42 may include at least one of a stainless material and an invar material. The shield stick 42 may include a stainless material having weak magnetism. Accordingly, in case that a magnetic force unit, for example, the magnetic force unit 60 of FIG. 1, applies a magnetic force to the mask assembly 40, the magnetism of the shield stick 42 interfering with the magnetic force applied by magnetic force unit 60 may be prevented.

The support stick 43 may be fixed on the mask frame 41 in a tensioned state across the opening area OA. The support stick 43 may have a length direction in the second direction, for example, the Y-axis direction. For example, end portions (e.g., opposite end portions) of the support stick 43 may be fixed on the mask frame 41 by a welding method. The support stick 43 may be positioned above the shield stick 42 crossing the shield stick 42 in the opening area OA.

For example, a support stick groove corresponding to the shape of the support stick 43 for accommodating end portions (e.g., opposite end portions) of the support stick 43 may be arranged in the mask frame 41. However, this is an example, and a separate groove is not arranged in the mask frame 41, and the support stick 43 may be arranged on the mask frame 41. The support stick 43 may prevent sagging of the mask sheet 44 by supporting the mask sheet 44 in the opening area OA.

The mask sheet 44 may include mask sheets, and may cover at least part of the opening area OA. The mask sheet 44 may be fixed on the mask frame 41 in a tensioned state and arranged to at least partially overlap the shield stick 42. The mask sheets 44 may be arranged parallel to each other. For example, the mask sheets 44 may be arranged parallel to each other in the second direction, for example, the Y-axis direction. For example, each of the mask sheets 44 may have a shape extending long in the first direction, for example, the X-axis direction. End end portions (e.g., opposite end portions) of the mask sheet 44 may be fixed on the mask frame 41, for example, by a welding method. Pattern holes H may be provided in the mask sheet 44. The pattern holes H may be through-holes formed to allow a deposition material passes through the mask sheet 44.

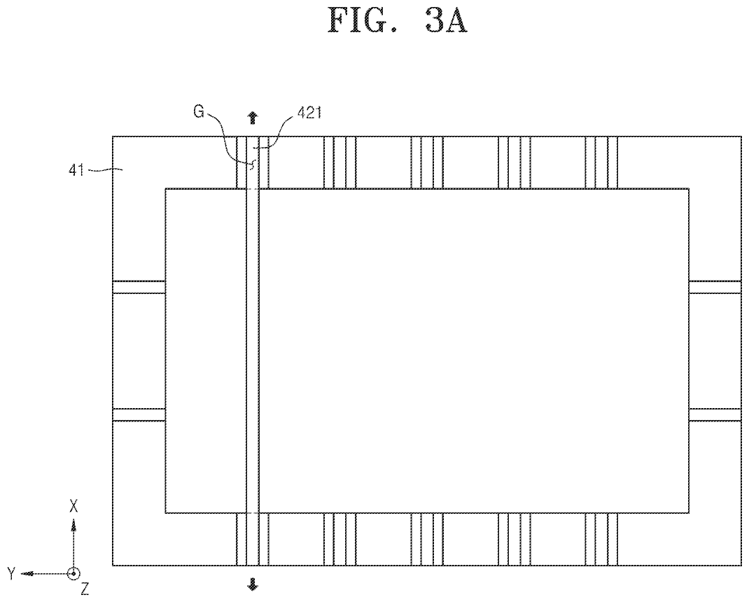

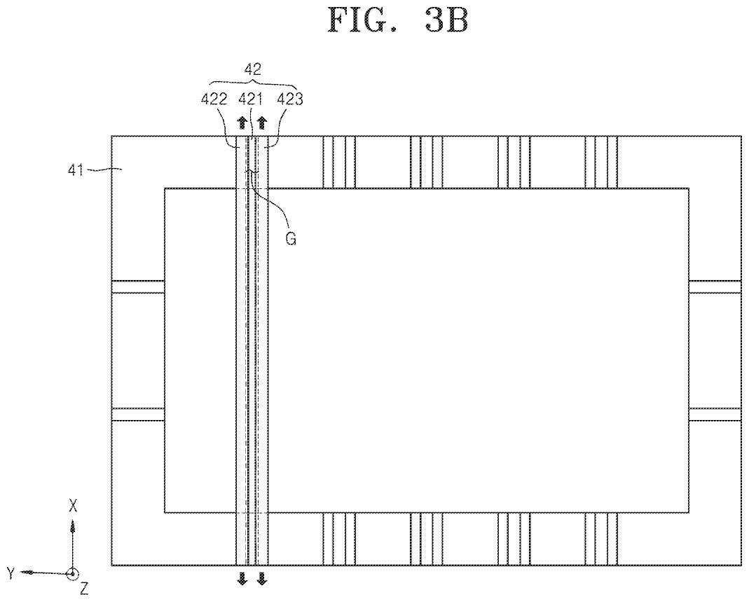

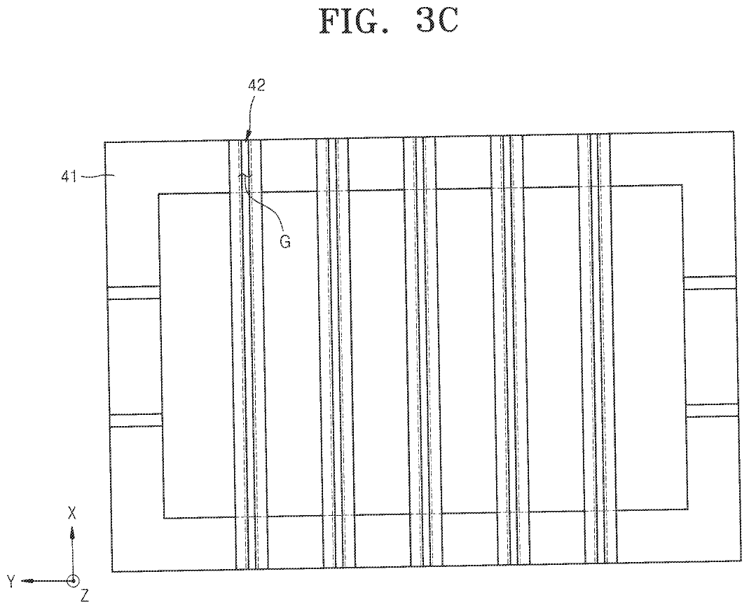

FIGS. 3A, 3B, and 3C are diagrams for explaining a process of a shield stick according to an embodiment being fixed on a mask frame.

Referring to FIGS. 3A, 3B, and 3C, the shield stick 42 may include a first shield member 421, a second shield member 422, and a third shield member 423, and each of the first shield member 421, the second shield member 422, and the third shield member 423 may be fixed on the mask frame 41.

Referring to FIG. 3A, the first shield member 421 may be fixed on the mask frame 41 in a tensioned state in the first direction, for example, the X-axis direction. The first shield member 421 may have a length direction parallel to the first direction, for example, the X-axis direction, and may be welded to the mask frame 41, in a state of being accommodated in the shield stick groove G.

Referring to FIG. 3B, the second shield member 422 and the third shield member 423 may be fixed on the mask frame 41 in a tensioned state in the first direction, for example, the X-axis direction. The second shield member 422 and the third shield member 423 may each have a length direction parallel to the first direction, for example, the X-axis direction, and may be welded on the mask frame 41, in a state of being accommodated in the shield stick groove G. In a plan view, as in FIG. 3B, the second shield member 422 and the third shield member 423 may be arranged to at least partially overlap the first shield member 421 with the first shield member 421 therebetween. For example, a right area, for example, an area in a negative Y-axis direction, of the second shield member 422 may overlap the first shield member 421. Furthermore, a left area, for example, an area in a positive Y-axis direction, of the third shield member 423 may overlap the first shield member 421.

Referring to FIG. 3C, each of the shield sticks 42, as described in FIGS. 3A and 3B, may be fixed on the mask frame 41 in a tensioned state in the first direction, for example, the X-axis direction. Each of the shield sticks 42 may have a length direction parallel to the first direction, for example, the X-axis direction, and may be welded to the mask frame 41, in a state of being accommodated in the shield stick groove G corresponding thereto. Although FIG. 3C illustrates that there are five shield sticks as the shield stick 42, this is a mere example, and the number of shield sticks is not limited thereto. For example, the shield stick 42 may be include only one shield stick.

As the shield stick 42 is fixed to the mask frame 41 in a tensioned state, a contractile force may be generated in the shield stick 42 in the first direction, for example, the X-axis direction. For example, a contractile force may be generated the first shield member 421, the second shield member 422, and the third shield member 423 in the first direction, for example, the X-axis direction. In a process of cleaning a mask assembly (e.g., the mask assembly 40 of FIG. 1), heat may be applied to the shield stick 42 so that the shield stick 42 may thermally expand. For example, due to the contractile force generated in the shield stick 42, a strain of the shield stick 42 (e.g., a ratio of a length of the shield stick 42 that extends to the total length of the shield stick 42) may be decreased.

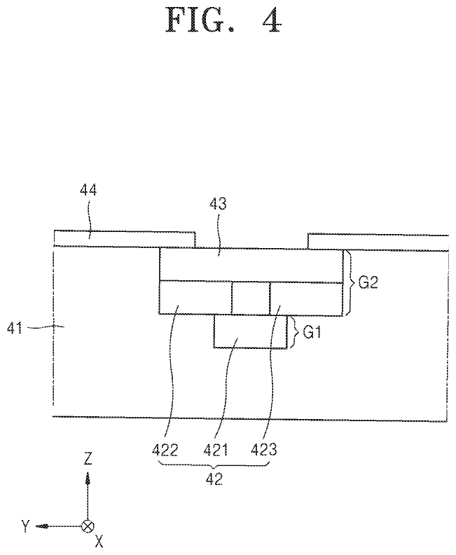

FIG. 4 is a schematic side view of a part of a mask assembly according to an embodiment, in which a part of the mask assembly 40 of FIG. 2 is viewed in a positive X-axis direction.

In a process of cleaning a mask assembly, for example, the mask assembly 40 of FIG. 1, as the fluidity of the shield stick 42 increases, an interference phenomenon that a part of the shield stick 42 is raised above the mask sheet 44 may be generated. The interference phenomenon may increase as the width of the shield stick 42 increases. Accordingly, to reduce the interference phenomenon between the shield stick 42 and the mask sheet 44, the shield stick 42 may be divided into members. For example, the shield stick 42 may include three or more shield members.

Referring to FIG. 4, the shield stick 42 may include the first shield member 421, the second shield member 422, and the third shield member 423. To accommodate the shield stick 42, the shield stick groove G corresponding to the shape of the shield stick 42 may be arranged in the mask frame 41. The shield stick groove G may include a first shield member groove G1 for accommodating the first shield member 421, and a second shield member groove G2 for accommodating the second shield member 422 and the third shield member 423.

The first shield member groove G1 may correspond to the shape of the first shield member 421. For example, the width of the first shield member groove G1 and the width of the first shield member 421 may be the same as each other. For example, the height of the first shield member groove G1 and the height of the first shield member 421 may be the same as each other. In the structure as above, the first shield member 421 may be accommodated in the first shield member groove G1.

The second shield member groove G2 may be arranged above the first shield member groove G1. The second shield member groove G2 may be arranged closer to the mask sheet 44 than the first shield member groove G1 is close to to the mask sheet 44. In the structure as above, the second shield member 422 and the third shield member 423 may be arranged above the first shield member 421. The second shield member 422 and the third shield member 423 may be arranged closer to the mask sheet 44 than the first shield member 421 is close to to the mask sheet 44. Accordingly, in a process of applying heat to the shield stick 42, such as a process of cleaning the mask assembly 40, in case that the shield stick 42 includes a stainless material having a relatively high thermal expansion coefficient, occurrence of the interference phenomenon that the shield stick 42 is raised (or shifted) above the mask sheet 44 may be reduced.

The width of the second shield member groove G2 may be smaller than the sum of the widths of the first to third shield members 421, 422, and 423. In the structure as above, the second shield member 422 may be arranged to at least partially overlap the first shield member 421. Furthermore, the third shield member 423 may be arranged to at least partially overlap the first shield member 421. For example, among three or more shield members, two shield members (421 and 422, or 421 and 423) that are arranged adjacent to each other may be arranged to at least partially overlap each other. Accordingly, as each of the second shield member 422 and the third shield member 423 overlaps the first shield member 421, in a process in which a deposition material passes through pattern holes, for example, the pattern holes H of FIG. 2, of the mask sheet 44, the deposition material may be prevented from passing between the first to third shield members 421, 422, and 423.

The width of the second shield member groove G2 may be greater than the sum of the width of the second shield member 422 and the width of the third shield member 423. In the structure as above, the second shield member 422 and the third shield member 423 may be spaced apart from each other in the second direction, for example, the Y-axis direction. However, this is an example, and the width of the second shield member groove G2 may be the same as the sum of the width of the second shield member 422 and the width of the third shield member 423. In the structure as above, the second shield member 422 and the third shield member 423 may be arranged in contact with each other.

The shield stick 42 may be fixed on the mask frame 41, in a state of being accommodated in the shield stick groove. The first shield member 421 may be fixed on the mask frame 41, in a state of being accommodated in the first shield member groove G1, and the second shield member 422 and the third shield member 423 may be fixed on the mask frame 41, in a state of being accommodated in the second shield member groove G2. For example, the shield stick 42 may be welded to the mask frame 41, in a state of being accommodated in the shield stick groove. However, this is an example, and the method of fixing the shield stick 42 on the mask frame 41 is not limited thereto. As the shield stick 42 is fixed on the mask frame 41, the interference phenomenon between the shield stick 42 and the mask sheet 44 may be reduced. Furthermore, durability, strength, and stability of the mask assembly 40 may be improved.

The depth of the second shield member groove G2 may be greater than the height of the second shield member 422 and the height of the third shield member 423. Accordingly, in a state in which the second shield member 422 and the third shield member 423 are accommodated in the second shield member groove G2, a space for arranging the support stick 43 above the second shield member 422 and the third shield member 423 may be secured. In the structure as above, the second shield member 422 and the third shield member 423 may be arranged above the first shield member 421, the support stick 43 may be arranged above the second shield member 422 and the third shield member 423, and the mask sheet 44 may be arranged above the support stick 43.

In the process of cleaning the mask assembly 40, the strain described above in FIG. 3C may be about 0% or more and about 0.03% or less. For example, the width of the shield stick 42 may be determined such that the strain of the shield stick 42 is about 0% or more and about 0.03% or less. However, this is an example, and the method of adjusting the strain of the shield stick 42 is not limited thereto. For example, a degree of tensioning the shield stick 42 before the shield stick 42 is fixed on the mask frame 41 may be determined such that the strain of the shield stick 42 is about 0% or more and about 0.03%.

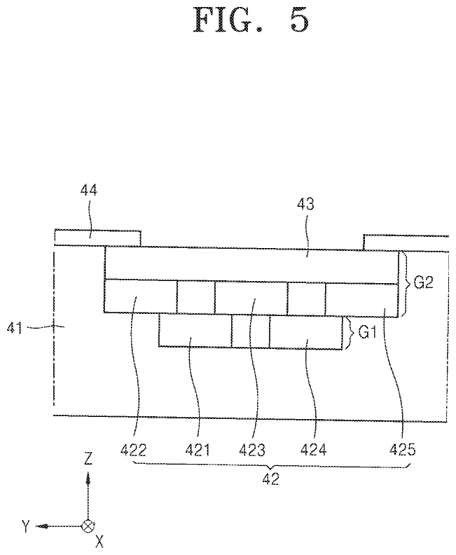

FIG. 5 is a schematic side view of a part of a mask assembly according to an embodiment. For convenience of explanation, descriptions redundant with those of FIG. 4 are omitted.

Referring to FIG. 5, the shield stick 42 may include the first shield member 421, the second shield member 422, the third shield member 423, a fourth shield member 424, and a fifth shield member 425. To accommodate the shield stick 42, the shield stick groove corresponding to the shape of the shield stick 42 may be arranged in the mask frame 41. The shield stick groove may include the first shield member groove G1 for accommodating the first shield member 421 and the fourth shield member 424, and the second shield member groove G2 for accommodating the second shield member 422, the third shield member 423, and the fifth shield member 425.

The first shield member 421 and the fourth shield member 424 may be accommodated in the first shield member groove G1. The width of the first shield member groove G1 may be greater than the sum of the widths of the first shield member 421 and the fourth shield member 424. In the structure as above, the first shield member 421 and the fourth shield member 424 may be spaced apart from each other in the second direction, for example, the Y-axis direction.

The second shield member 422, the third shield member 423, and the fifth shield member 425 may be accommodated in the second shield member groove G2. The second shield member groove G2 may be arranged above the first shield member groove G1. For example, the second shield member groove G2 may be arranged closer to the mask sheet 44 than the first shield member groove G1 is close to the mask sheet 44. In the structure as above, the second shield member 422, the third shield member 423, and the fifth shield member 425 may be arranged above the first shield member 421 and the fourth shield member 424. For example, the second shield member 422, the third shield member 423, and the fifth shield member 425 may be arranged closer to the mask sheet 44 than the first shield member 421 and the fourth shield member 424 are close to the mask sheet 44.

The width of the second shield member groove G2 may be greater than the sum of the widths of the second shield member 422, the third shield member 423, and the fifth shield member 425. In the structure as above, the second shield member 422, the third shield member 423, and the fifth shield member 425 may be spaced apart from each other in the second direction, for example, the Y-axis direction.

The shield stick 42 may be fixed on the mask frame 41, in a state of being accommodated in the shield stick groove. The first shield member 421 and the fourth shield member 424 may be fixed on the mask frame 41, in a state of being accommodated in the first shield member groove G1, the second shield member 422 and the fifth shield member 425 may be fixed on the mask frame 41, in a state of being accommodated in the second shield member groove G2, and the third shield member 423 may be on at least one of the first shield member 421 and the fourth shield member 424, in a state of being accommodated in the second shield member groove G2.

The depth of the second shield member groove G2 may be greater than the height of the second shield member 422, the height of the third shield member 423, and the height of the fifth shield member 425. Accordingly, in a state in which the second shield member 422, the third shield member 423, and the fifth shield member 425 are accommodated in the second shield member groove G2, a space in which the support stick 43 is arranged above the second shield member 422, the third shield member 423, and the fifth shield member 425 may be formed. In the structure as above, the second shield member 422, the third shield member 423, and the fifth shield member 425 may be arranged above the first shield member 421 and the fourth shield member 424, and the support stick 43 may be arranged above the second shield member 422, the third shield member 423, and the fifth shield member 425.

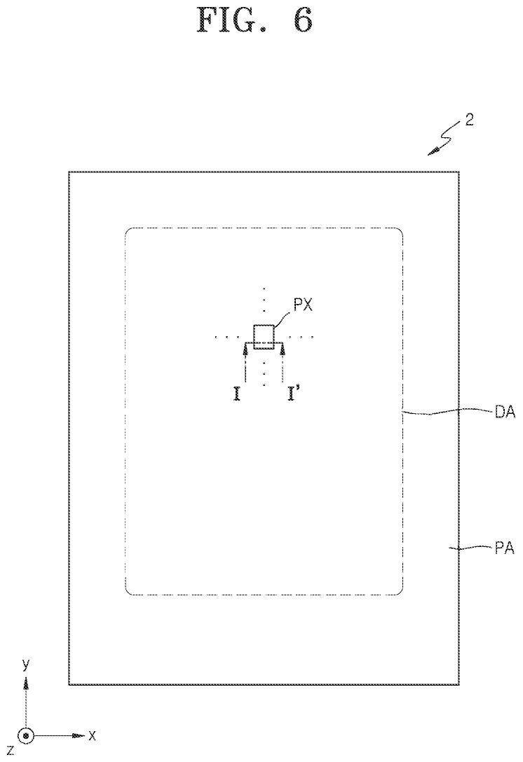

FIG. 6 is a schematic plan view of a display device 2 manufactured by a method of manufacturing a display device, according to an embodiment.

Referring to FIG. 6, the display device 2 manufactured according to an embodiment may include a display area DA and a peripheral area PA positioned outside the display area DA. The display device 2 may provide an image through an array of pixels PX two-dimensionally arranged in the display area DA.

The peripheral area PA may be an area that does to provide an image and may entirely or partially surround the display area DA. A driver and the like for providing an electrical signal or power to a pixel circuit corresponding to each of the pixels PX may be arranged in the peripheral area PA. A pad that is an area where an electronic device, a printed circuit board, and the like may be connected (e.g., electrically connected) may be arranged in the peripheral area PA.

In the following description, although the display device 2 includes an organic light-emitting diode (OLED) as a light-emitting element, the display device 2 according to an embodiment is not limited thereto. In another example, the display device 2 may be a light-emitting display device including an inorganic light-emitting diode, e.g., an inorganic light-emitting display device. An inorganic light-emitting diode may include a PN diode including inorganic material semiconductor-based materials. In case that a voltage is applied to a PN junction diode in a forward direction, holes and electrons may be injected, and energy generated by a recombination of the holes and the electrons may be converted into light energy so as to emit light of a certain color. The above-described inorganic light-emitting diode may have a width of several to hundreds of micrometers, and in some embodiments, an inorganic light-emitting diode may be referred to a micro LED. In another example, the display device 2 may be a quantum-dot light-emitting display device.

The display device 2 may be applied to a display screen of not only a portable electronic device, such as a mobile phone, a smart phone, a tablet personal computer (PC), a mobile communication terminal, an electronic organizer, an electronic book, a portable multimedia player (PMP), a navigation device, an ultra-mobile PC (UMPC), and the like, but also various products, such as televisions, notebook computers, monitors, billboards, internet of things (IOT) apparatuses, and the like. Furthermore, the display device 2 according to an embodiment may be used for a wearable device, such as a smart watch, a watch phone, a glasses type display, a head mounted display (HMD), and the like. Furthermore, the display device 2 according to an embodiment may be applied to an instrument panel of a vehicle, a center information display (CID) arranged in a center fascia or dashboard of a vehicle, a room mirror display in lieu of a side mirror of a vehicle, and a display screen arranged in the backside of the front seat as an entertainment device for the rear seat of a vehicle.

FIG. 7 is a schematic cross-sectional view of a display device manufactured by a method of manufacturing a display device, according to an embodiment, which may correspond to a cross-sectional view of the display device taken along line I-I′ of FIG. 6.

Referring to FIG. 7, the display device 2 may have a stack structure of the substrate 100, a pixel circuit layer PCL, a display element layer DEL, and an encapsulation layer 300. The display substrate DS (see FIG. 1) described above may be formed by stacking at least any one of the pixel circuit layer PCL, the display element layer DEL, and the encapsulation layer 300 on, for example, the substrate 100 that is in a process of manufacturing the display device 2.

The substrate 100 may have a multilayer structure including a base layer including polymer resin and an inorganic layer. For example, the substrate 100 may include a base layer including polymer resin and a barrier layer of an inorganic insulating layer. For example, the substrate 100 may include a first base layer 101, a first barrier layer 102, a second base layer 103, and a second barrier layer 104, which are sequentially stacked. The first base layer 101 and the second base layer 103 may each include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), or/and cellulose acetate propionate (CAP), and the like. The first barrier layer 102 and the second barrier layer 104 may each include an inorganic insulating material, such as a silicon oxide, a silicon oxynitride, and/or a silicon nitride. The substrate 100 may be flexible.

The pixel circuit layer PCL may be disposed on substrate 100. FIG. 7 illustrates that the pixel circuit layer PCL includes a thin film transistor TFT, and a buffer layer 111, a first gate insulating layer 112, a second gate insulating layer 113, an interlayer insulating layer 114, a first planarization insulating layer 115, and a second planarization insulating layer 116, which are disposed below or/and above constituent elements of the thin film transistor TFT.

The buffer layer 111 may prevent or reduce infiltration of foreign materials, such as moisture or external air from under the substrate 100, and provide a planarized surface to the substrate 100. The buffer layer 111 may include an inorganic insulating material, such as a silicon oxide, a silicon oxynitride, and a silicon nitride, and may have a single layer structure or a multilayer structure including the above-described material.

The thin film transistor TFT on the buffer layer 111 may include a semiconductor layer Act, and the semiconductor layer Act may include polysilicon. In another example, the semiconductor layer Act may include amorphous silicon, an oxide semiconductor, an organic semiconductor, and the like. The semiconductor layer Act may include a channel region C, and a drain region D and a source region S arranged at both sides of the channel region C. A gate electrode GE may overlap the channel region C.

The gate electrode GE may include a low-resistance metal material. The gate electrode GE may include a conductive material, such as molybdenum (Mo), aluminum (Al), copper (Cu), titanium (Ti), and the like conductive material, and may be formed in a multilayer or single layer including the material.

The first gate insulating layer 112 between the semiconductor layer Act and the gate electrode GE may include an inorganic insulating material, such as a silicon oxide (SiO₂), a silicon nitride (SiNX), a silicon oxynitride (SiON), an aluminum oxide (Al₂O₃), a titanium oxide (TiO₂), a tantalum oxide (Ta₂O₅), a hafnium oxide (HfO₂), a zinc oxide (ZnOX) or the like. ZnOX may include a zinc oxide (ZnO) and/or a zinc peroxide (ZnO₂).

The second gate insulating layer 113 may cover the gate electrode GE. The second gate insulating layer 113 may include inorganic insulating material, such as SiO₂, SiNX, SiON, Al₂O₃, TiO₂, Ta₂O₅, HfO₂, ZnOX, and the like. ZnOX may include ZnO and/or ZnO₂.

An upper electrode Cst2 of a storage capacitor Cst may be arranged above the second gate insulating layer 113. The upper electrode Cst2 may overlap the gate electrode GE thereunder. In this state, the gate electrode GE and the upper electrode Cst2 may overlap each other, and the second gate insulating layer 113 may be between the gate electrode GE and the upper electrode Cst2. The gate electrode GE, the upper electrode Cst2, and the second gate insulating layer 113 may form the storage capacitor Cst. For example, the gate electrode GE may function as a lower electrode Cst1 of the storage capacitor Cst.

As such, the storage capacitor Cst may overlap the thin film transistor TFT. In some embodiments, the storage capacitor Cst may not overlap the thin film transistor TFT.

The upper electrode Cst2 may include Al, platinum (Pt), palladium (Pd), silver (Ag), magnesium (Mg), gold (Au), nickel (Ni), neodymium (Nd), iridium (Jr), chromium (Cr), calcium (Ca), Mo, Ti, tungsten (W), and/or Cu, and may be a single layer or a multilayer of the above-described material.

The interlayer insulating layer 114 may cover the upper electrode Cst2. The interlayer insulating layer 114 may include SiO₂, SiNX, SiON, Al₂O₃, TiO₂, Ta₂O₅, HfO₂, ZnOX, or the like. ZnOX may include ZnO and/or ZnO₂. The interlayer insulating layer 114 may be a single layer or a multilayer including the above-described inorganic insulating material.

A drain electrode DE and a source electrode SE may each be disposed above the interlayer insulating layer 114. The drain electrode DE and the source electrode SE may be respectively connected to the drain region D and the source region S via contact holes formed in insulating layers thereunder. The drain electrode DE and the source electrode SE may each include a material having excellent conductivity. The drain electrode DE and the source electrode SE may include a conductive material including Mo, Al, Cu, Ti, and the like, and may be formed in a multilayer or a single layer including the above-described materials. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating material including a general purpose polymer, such as polymethylmethacrylate (PMMA) or polystyrene (PS), polymer derivatives having a phenolic group, acrylic polymer, imide-based polymer, aryl ether-based polymer, amide-based polymer, fluorine-based polymer, p-xylene-based polymer, vinyl alcohol-based polymer, and blends thereof.

The second planarization insulating layer 116 may be disposed on the first planarization insulating layer 115. The second planarization insulating layer 116 and the first planarization insulating layer 115 may include the same material as each other. The second planarization insulating layer 116 may include an organic insulating material including a general purpose polymer, such as PMMA or PS, polymer derivatives having a phenolic group, acrylic polymer, imide-based polymer, aryl ether-based polymer, amide-based polymer, fluorine-based polymer, p-xylene-based polymer, vinyl alcohol-based polymer, and blends thereof.

The display element layer DEL may be disposed on the pixel circuit layer PCL having the above-described structure. The display element layer DEL may include an organic light-emitting diode OLED as a display element, e.g., a light-emitting element, and the organic light-emitting diode OLED may have a stack structure of a pixel electrode 210, an intermediate layer 220, and a common electrode 230. The organic light-emitting diode OLED may emit, for example, red, green, or blue light, or red, green, blue, or white light. The organic light-emitting diode OLED may emit light through an emission area, and the emission area may be defined as a pixel PX.

The pixel electrode 210 of the organic light-emitting diode OLED may be connected (e.g., electrically connected) to the thin film transistor TFT via contact holes formed in the second planarization insulating layer 116 and the first planarization insulating layer 115 and a contact metal CM formed on the first planarization insulating layer 115.

The pixel electrode 210 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In another example, the pixel electrode 210 may include a reflective film including Ag, Mg, Al, Pt, Pd, Au, Ni, Nd, Jr, Cr, or a compound thereof. In another example, the pixel electrode 210 may further include a film including ITO, IZO, ZnO, or In₂O₃ and formed above/below the above-described reflective film.

A pixel defining layer 117 having an opening 1170P that exposes a central portion of the pixel electrode 210 is disposed on the pixel electrode 210. The pixel defining layer 117 may include an organic insulating material and/or an inorganic insulating material. The opening 1170P may define the emission area of the light emitted from the organic light-emitting diode OLED. For example, the size/width of the opening 1170P may correspond to the size/width of the emission area. Accordingly, the size and/or width of the pixel PX may be dependent on the size and/or width of the opening 1170P of the pixel defining layer 117 corresponding thereto.

The intermediate layer 220 may include a light-emitting layer 222 corresponding to (or overlapping) the pixel electrode 210. The light-emitting layer 222 may include a polymer or low molecular weight organic material for emitting light of a certain color. In another example, the light-emitting layer 222 may include an inorganic light-emitting material or quantum dots.

In an embodiment, the intermediate layer 220 may include a first functional layer 221 and a second functional layer 223 respectively disposed below and above the light-emitting layer 222. The first functional layer 221 may include, for example, a hole transport layer HTL, or the HTL and a hole injection layer HIL. The second functional layer 223, as a constituent element disposed above the light-emitting layer 222, may include an electron transport layer ETL and/or an electron injection layer EIL. The first functional layer 221 and/or the second functional layer 223 may be common layers formed to cover (e.g., entirely cover) the substrate 100, like the common electrode 230 to be described below.

The common electrode 230 may be disposed on the pixel electrode 210 and may overlap the pixel electrode 210. The common electrode 230 may include a conductive material having a low work function. For example, the common electrode 230 may include a transparent layer (or a semi-transparent layer) including Ag, Mg, Al, Pt, Pd, Au, Ni, Nd, Jr, Cr, lithium (Li), Ca, an alloy thereof, or the like. In another example, the common electrode 230 may further include a layer including ITO, IZO, ZnO, or In₂O₃ on the transparent layer (or a semi-transparent layer) including the above-described material. The common electrode 230 may be integral with each other to cover (e.g., entirely cover) the substrate 100.

The encapsulation layer 300 may be disposed on the display element layer DEL and may cover the display element layer DEL. The encapsulation layer 300 may include at least one inorganic encapsulation layer and at least one organic encapsulation layer. In an embodiment, FIG. 12 illustrates that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials of Al₂O₃, TiO₂, Ta₂O₅, HfO₂, ZnOX, SiO₂, SiNX, and SiON. The organic encapsulation layer 320 may include a polymer-based material. The polymer-based material may include acrylic resin, epoxy-based resin, polyimide, polyethylene, and the like. In an embodiment, the organic encapsulation layer 320 may include acrylate. The organic encapsulation layer 320 may be formed by curing a monomer or by coating a polymer. The organic encapsulation layer 320 may be transparent.

For example, a touch sensor layer may be disposed on the encapsulation layer 300, and an optical functional layer may be disposed on the touch sensor layer. The touch sensor layer may receive (or sense) an external input, for example, coordinates information according to a touch event. The optical functional layer may reduce reflectivity of light (e.g., external light) input from the outside toward a display device, and/or improve the color purity of light emitted from the display device. In an embodiment, the optical functional layer may include a retarder and/or a polarizer. The retarder may be of a film type or a liquid crystal coating type, and may include a λ/2 retarder and/or a λ/4 retarder. The polarizer may also be of a film type or a liquid crystal coating type. The film type may include a stretchable synthetic resin film, and the liquid crystal coating type may include liquid crystals arranged in a certain array. The retarder and the polarizer may further include a protective film.

An adhesive member may be provided between the touch electrode layer and the optical functional layer. The adhesive member may employ any general member known in the technical field without limitation. The adhesive member may include a pressure sensitive adhesive (PSA).

According to one or more embodiments, the deposition quality of a deposition material may be improved by preventing the interference phenomenon between the mask sheet and the shield stick.

The effects of the disclosure are not limited to the above-described effects, and other various effects that are not described in the specification may be clearly understood from the following descriptions by one skilled in the art to which the disclosure belongs.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An apparatus for manufacturing a display device, the apparatus comprising:
a chamber;
a mask assembly disposed in the chamber and facing a display substrate; and
a deposition source disposed in the chamber and facing the mask assembly, the deposition source that supplies a deposition material such that the deposition material passes through the mask assembly and is deposited on the display substrate, wherein
the mask assembly comprises:
a mask frame including an opening area;
at least one shield stick fixed on the mask frame in a tensioned state across the opening area of the mask frame; and
a plurality of mask sheets covering at least part of the opening area and at least partially overlapping the at least one shield stick,
the at least one shield stick comprises:
a first shield member;
a second shield member at least partially overlapping the first shield member; and
a third shield member at least partially overlapping the first shield member, and
the second shield member and the third shield member are disposed above the first shield member and are closer to the plurality of mask sheets than the first shield member is close to the plurality of mask sheets.

2. The apparatus of claim 1, wherein a shield stick groove is disposed in the mask frame and accommodates end portions of the at least one shield stick.

3. The apparatus of claim 2, wherein in case that the at least one shield stick is accommodated in the shield stick groove, the first shield member is fixed on the mask frame.

4. The apparatus of claim 3, wherein in case that the at least one shield stick is accommodated in the shield stick groove, the second shield member and third shield member are fixed on the mask frame.

5. The apparatus of claim 1, wherein the at least one shield stick comprises at least one of a stainless material and an invar material.

6. The apparatus of claim 1, wherein the at least one shield stick further comprises:
a fourth shield member at least partially overlapping the third shield member, disposed below the third shield member, and being closer to the deposition source than the third shield member is close to the deposition source; and
a fifth shield member at least partially overlapping the fourth shield member, disposed above the fourth shield member, and being closer to the plurality of mask sheets than the fourth shield member is close to the plurality of mask sheets.

7. A mask assembly comprising:
a mask frame including an opening area;
at least one shield stick fixed on the mask frame in a tensioned state across the opening area of the mask frame; and
a plurality of mask sheets covering at least part of the opening area of the mask frame and at least partially overlapping the at least one shield stick, wherein
the at least one shield stick comprises three or more shield members,
two shield members of the three or more shield members are adjacent to each other and at least partially overlap each other, and
at least one of the three or more shield members is disposed below the two shield members that are adjacent to each other.

8. The mask assembly of claim 7, wherein a shield stick groove is disposed in the mask frame and accommodates end portions of the at least one shield stick.

9. The mask assembly of claim 8, wherein in case that the at least one shield stick is accommodated in the shield stick groove, the at least one of the three or more shield members is fixed on the mask frame.

10. The mask assembly of claim 9, wherein in case that the at least one shield stick is accommodated in the shield stick groove, the three or more shield members are fixed on the mask frame.

11. The mask assembly of claim 7, wherein the at least one shield stick comprises at least one of a stainless material and an invar material.

12. A method of manufacturing a display device, the method comprising:
disposing a display substrate and a mask assembly in a chamber;
depositing a deposition material on the display substrate, the deposition material being supplied from a deposition source to pass through the mask assembly; and
cleaning the mask assembly, wherein
the mask assembly comprises:
a mask frame including an opening area;
at least one shield stick fixed on the mask frame in a tensioned state across the opening area of the mask frame; and
a plurality of mask sheets covering at least part of the opening area of the mask frame and at least partially overlapping the at least one shield stick,
the at least one shield stick comprises:
a first shield member;
a second shield member at least partially overlapping the first shield member; and
a third shield member at least partially overlapping the first shield member, and
the second shield member and the third shield member are disposed above the first shield member and are closer to the plurality of mask sheets than the first shield member is close to the plurality of mask sheets.

13. The method of claim 12, wherein a strain that is a ratio of a length of a shield stick deformed due to a temperature difference in the cleaning of the mask assembly to a length of a shield stick tensioned in the disposing of the display substrate and the mask assembly is about 0% or more and about 0.03% or less.

14. The method of claim 13, wherein a width of the at least one shield stick is determined such that a strain of the at least one shield stick is about 0% or more and about 0.03% or less.

15. The method of claim 13, wherein a degree of tensioning the at least one shield stick before the at least one shield stick is fixed on the mask frame is determined such that a strain of the at least one shield stick is about 0% or more and about 0.03% or less.

16. The method of claim 12, wherein a shield stick groove disposed in the mask frame and accommodates end portions of the at least one shield stick.

17. The method of claim 16, wherein in case that the at least one shield stick is accommodated in the shield stick groove, the first shield member is fixed on the mask frame.

18. The method of claim 17, wherein in case that the at least one shield stick is accommodated in the shield stick groove, the second shield member and third shield member are fixed on the mask frame.

19. The method of claim 12, wherein the at least one shield stick comprises at least one of a stainless material and an invar material.

20. The method of claim 12, wherein the at least one shield stick further comprises:
a fourth shield member at least partially overlapping the third shield member, disposed below the third shield member, and being closer to the deposition source than the third shield member is close to the deposition source; and
a fifth shield member at least partially overlapping the fourth shield member, disposed above the fourth shield member, and being closer to the plurality of mask sheets than the fourth shield member is closer to the plurality of mask sheets.
